(19) United States
(12) Patent Application Publication
(10) Pub. No.: US 2009/0256638 A1
(43) Pub. Date: Oct. 15, 2009

(54) Atomic frequency standard based on enhanced modulation efficiency semiconductor lasers

(76) Inventors: Michael Rosenbluh, Ramat Gan (IL); Nemi Gavra, Ramat Gan (IL); Valentina Ruseva, Ramat Gan (IL); Avinoam Stern, Jerusalem (IL); Gad Eisenstein, Haifa (IL); Benny Levy, Jerusalem (IL)

Correspondence Address: SIMON KAHN - PYI Tech, Ltd.;c/o LANDONIP, INC, 1725 Jamieson Avenue, ALEXANDRIA, VA, 22314, US

(21) Appl. No.: 12/385,022

(22) Filed: Mar. 30, 2009

Related U.S. Application Data
(60) Provisional application No. 61/064,820, filed on Mar. 28, 2008.

(51) Int. Cl. H03L 7/00

(52) U.S. Cl. 331/3

(57) ABSTRACT

This invention concerns the realization of a Coherent-Population-Trapping (CPT) atomic frequency standard using a laser which has feedback from an external cavity. The mode spacing of the external cavity is adjusted to equal the hyperfine transition frequency of the atomic vapor or a sub-harmonic of it. The external cavity enhances the modulation response at the required atomic transition and improves the stability of the frequency standard.

### SUMMARY OF THE INVENTION

This invention concerns the realization of a Coherent-Population-Trapping (CPT) atomic frequency standard using a laser which has feedback from an external cavity. The external cavity enhances the modulation response at the required atomic transition frequency and also enables active mode-locking. The mode spacing of the external cavity is adjusted to equal the hyperfine transition frequency of the atomic vapor or a sub-harmonic of it. A possible laser for the materialization of the invention is that of a VCSEL type. Alternatively, a DFB, DBR or a Fabry Perot laser with one of its facets AR coated can be used.

We describe 3 possible configurations to excite the atomic vapor and to stabilize the output frequency:
1. External cavity enhanced laser with conventional FLL
2. External cavity enhanced laser and injection locked oscillator
3. External cavity enhanced laser and direct looping

The atomic vapor used in the cell could be Rubidium, Cesium, Potassium, Sodium or any other element in which CPT phenomenon could be observed. Furthermore, it could be any solid or soft material in which the CPT could be observed.

1. Field of the Invention

The present invention relates generally to the field of atomic frequency standards. In particular it relates to vapor cell atomic frequency standards in which the phenomenon of coherent population trapping is used.

2. Description of Prior Art

There are two types of vapor cell frequency standards: an older one which is based on the phenomenon of Intensity Optical Pumping (IOP) and a newer one which is based on the phenomenon of Coherent-Population-Trapping (CPT) also known as Electromagnetically-Induced-Transparency (EIT).

This invention however concerns the realization of a Coherent-Population-Trapping (CPT) atomic frequency standard using resonant external cavity enhancement of the laser source. The CPT phenomenon occurs with the so called A configuration. Under CPT the atomic vapor is transparent with respect to the two incident optical waves when the difference in their frequencies matches the hyperfine frequency which is equal to the separation between the two m-sub-F=0 hyperfine levels (for details see J. Vanier, “Atomic clocks based on coherent population trapping: a review” Appl. Phys. B 81, 441-442, 2005).

In a conventional CPT based Atomic Frequency Standard one modulates a laser to obtain the two optical fields at the two different frequencies required to observe the CPT phenomena. This is performed by modulating the supply current of the laser at a frequency near half of the hyperfine transition frequency. When talking about atomic clocks it is common to call it the “clock frequency”. In the said modulated laser, sidebands are generated which are separated by the said clock frequency and integer multiples of it. The laser light is transmitted through an atomic vapor cell which becomes transparent due to the CPT when the modulation frequency matches the clock frequency. The vapor transparency is used to lock the oscillator that generates the modulation frequency to the hyperfine atomic frequency.

The atomic vapor used in the cell could be Rubidium, Cesium, Potassium, Sodium or any other element in which CPT phenomenon could be observed. Furthermore, it could be any solid or soft material in which the CPT could be observed.

A prior art materialization of a CPT based atomic clock is shown in FIG. 1.

A modulated laser (1) emits light at a wavelength corresponding to the D1 or D2 transition of an alkali atom (D1=795 nm for Rb87). The modulation is performed by a microwave generator (9). The modulated light from the laser is transmitted through a quarter lamda plate (2), then through an atomic vapor cell (3) (Rb87 or other) and is detected by a photo-detector (4) whose output signal is amplified by an I to V amplifier (6). The signal is then demodulated by a Mixer ((7) using a low frequency (below 100 kHz) obtained from a low f modulator (5), integrated by an integrator (8) and controls a microwave generator (9), closing the loop. The said microwave generator (9) provides two outputs, one is FM modulated by the said low f generator (5) and its output is injected to the laser control current. The other output, unmodulated, is provided for the user. Not shown in the figure is an additional optional. synthesizer that transforms the microwave generator frequency to a standard used frequency (e.g., 10 MHz, 100 MHz).

### DESCRIPTION OF THE INVENTION

In the present invention we use a laser coupled to an external cavity where the cavity mode spacing is adjusted to equal the hyperfine transition of the atomic vapor. i.e., 2*c/2l equals the clock frequency or a sub-harmonic of it. l is the length of the cavity. The role of the external cavity is to enhance the modulation response of the laser at the drive frequency (which means that a large optical modulation can be achieved with a low RF drive power) or to enable active mode locking. For Rubidium the clock frequency is about 6.8 GHz. Furthermore, under some conditions, the laser may exhibit passive (self starting) mode locking without the external stimulation. For the laser we may use a VCSEL type or any other suitable laser.

Additional details for external cavity modulation enhancement are found in the paper: “Enhancement in microwave modulation efficiency of vertical cavity surface-emitting laser by optical feedback” by Nemi Gavra, Valentina Ruseva, and Michael Rosenbluh.

In the following we describe 3 possible configurations to excite the atomic vapor and to stabilize the output frequency. These are described in the following sections.

(a) External Cavity Enhanced Laser with Conventional FLL

In this configuration we use a conventional Frequency Lock Loop (FLL) to lock an external oscillator to the atomic transition. We place the vapor cell outside the laser cavity and use an external oscillator to generate a frequency equals to half the clock frequency.

Possible materialization is shown in FIG. 2. A modulated laser (10), with an external mirror (11) that forms an external cavity, emits light at a wavelength corresponding to the D1 or D2 transition of an alkali atom (D1=795 nm for Rb87). The laser could be a VCSEL or another type. The mode spacing of the external cavity is adjusted to a half of the hyperfine 0-0 transition frequency of the alkali atom (about 3.4 GHz for Rb87—half the clock frequency). The modulation is performed by a microwave generator (19) at the said half of the clock frequency. The modulated light from the laser is transmitted through a quarter lamda plate (12), then through an atomic vapor cell (13) (Rb87 or other) and is detected by a Photo-detector (14) whose output signal is amplified by an I to V amplifier (16). The signal is then demodulated by a Mixer (17) using a low frequency (below 100 kHz) obtained from a Low f generator (15), integrated by an integrator (18) and control the said microwave generator (19) closing the loop. The said microwave generator (19) provides two outputs, one is FM modulated (by the said Low f generator (15)) which is injected to the laser control current. The other output, un-modulated, is provided for the user. Not shown in the figure is an additional optional synthesizer that transforms the microwave generator frequency to a standard used frequency (e.g., 10 MHz, 100 MHz).

This configuration possesses the following advantages over the prior art clock:
(1) An enhanced modulation efficiency which reduces the necessary power required from microwave generator. The microwave oscillator has a substantial contribution to the power consumption budget of the clock.
(2) The external cavity laser has a longer resonator which increases the damping time of the intra-cavity light, thus allows for lower phase noise and a smaller emission linewidth. As a result the signal to noise ratio and the stability of the clock is improved.

### (b) External Cavity Enhanced Laser and Injection Locked Oscillator

In this configuration we eliminate the following elements used in the first configuration (External cavity enhanced Laser with Conventional FLL): (a) The said Low f generator, (b) The said Integrator (c) The said Microwave generator (d) The said Mixer. We replace the (slow) Photo-detector with a fast one. The fast detector detects the light modulation at half the clock frequency. The photo-diode output is then used for injection-locking of the microwave oscillator which is used, in turn, to modulate the laser current. This way the whole loop functions as a microwave optoelectronic oscillator, oscillating at the full or at the half of the hyperfine frequency when the vapor becomes transparent.

A possible materialization for this configuration is shown in FIG. 3.

A modulated laser (20) with an external mirror (21) that forms an external cavity emits light at a wavelength corresponding to the D1 or D2 transition of an alkali atom. The laser could be a VCSEL or another type. The mode spacing of the external cavity is adjusted to half the hyperfine 0-0 transition frequency of the alkali atom The modulated light is transmitted through a quarter lamda plate (22), then through an atomic vapor cell (23) and detected by a Photo-detector (24) whose signal is amplified by microwave amplifier (25) and injected into a microwave oscillator (26) for injection-locking the oscillator to half of the said clock frequency. The said microwave oscillator is used to modulate the laser current at half the said clock frequency. Again, not shown in the figure is an additional optional synthesizer that transforms the microwave generator frequency to a standard used frequency (e.g., 10 MHz, 100 MHz).

This configuration possesses the following advantages in using this configuration:
(1) An enhanced modulation efficiency, as described before
(2) An improved signal-to-noise ratio and improved clock's stability as described above.
(3) Fewer components compare to the prior art clock configuration

### (c) External Cavity Enhanced Laser and Direct Looping

In this configuration we eliminate the μ-wave oscillator altogether by injection the output of the fast I/V converter to the current modulation input of the laser. This configuration is shown in FIG. 4. A modulated laser (27) with an external mirror (28) that forms an external cavity emits light at a wavelength corresponding to the D1 or D2 transition of an alkali atom. The mode spacing of the external cavity is adjusted to half the hyperfine 0-0 transition frequency of the alkali atom. The modulated light is transmitted through a quarter lamda plate (29), then through an atomic vapor cell (30) and detected by a Photo-detector (31). The said Photo-detector output signal is amplified by microwave amplifier (32), phase adjusted (33) and injected into the laser supply current, modulating its emission at half the said clock frequency. This configuration acts as an opto-electronics oscillator which is stabilized by the atomic vapor hyperfine transition.

Not shown in the figure is the possibility of adding electronic filters in the feedback loop to narrow the frequency range response. Additionally, not shown in the figure is an optional synthesizer that transforms the microwave generator frequency to a standard used frequency (e.g., 10 MHz, 100 MHz).

This configuration possesses the following advantages in using this configuration:
(1) An enhanced modulation efficiency, as described before. This enables a stable operation of the loop with even fewer components.
(2) As mentioned in (1) this materialization contains very few components in comparison to a prior art clock configuration.

### DESCRIPTION OF THE DRAWINGS

FIG. 1: Prior state materialization of CPT clock

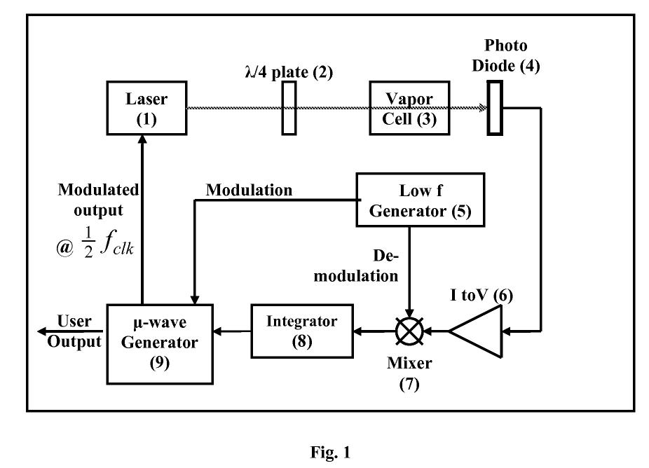

FIG. 2: External cavity enhanced laser with conventional FLL

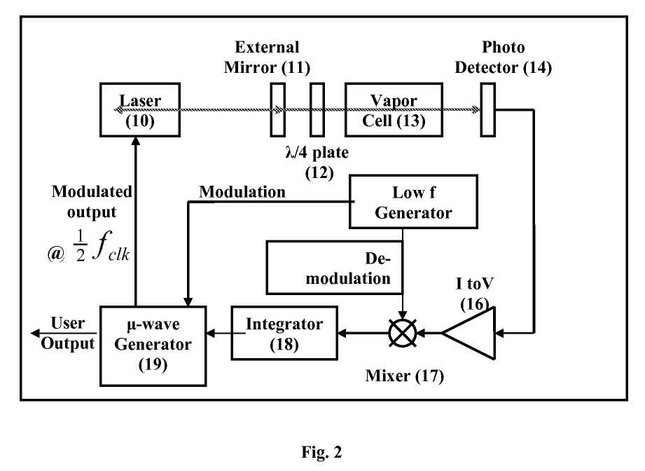

FIG. 3: External cavity enhanced laser and Injection Locking

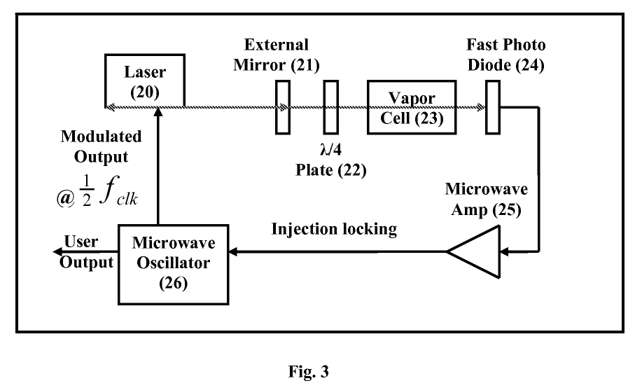

FIG. 4: External cavity enhanced locking and direct looping

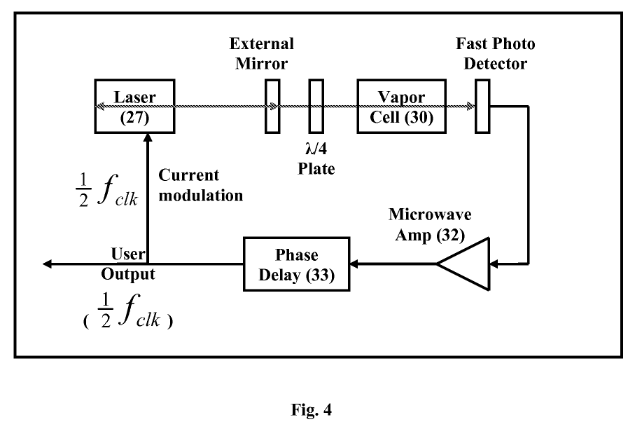

What is claimed is:

1. An atomic frequency standard comprising:
a. An external cavity laser whose emitted wavelength corresponds to either of the D1 or the D2 transition of an alkali metal atom such as Rb, Cs or other,
b. The external cavity length is adjusted to have a mode spacing which corresponds to the 0-0 hyperfine ground state transition frequency of the said alkali atom divided by an integer number,
c. A combination of optical components that set the state of polarization of the light to be circularly polarized,
d. A cell containing a mixture of alkali metal atoms and a mixture of buffer gases non reactive with said alkali metal atoms, said mixture being selected to minimize the temperature coefficient within said cell;
e. A microwave generator that generates a frequency equals to the said hyperfine frequency of said alkali metal atoms (the “clock transition”) divided by an integer number,
f. A Low Frequency (LF) generator that generates a frequency below ˜100 kHz and is used to Phase Modulate (PM) the said microwave generator output. The LF generator is also used to for the demodulation signal defined in #i,
g. The said microwave generator output is used to Amplitude Modulate (AM) the current of the said laser. The laser emission wavelength is thus amplitude, frequency and phase modulated,
h. A photo-detector placed behind the vapor cell is used to detect the variations in the intensity of the light transmitted through said cell,
i. An FLL (Frequency Lock Loop) circuit that de-modulates the variations in the light intensity and locks the Microwave generator output frequency to the said hyperfine frequency. The de-modulation frequency is obtained from the said microwave generator.

2. The standard of claim 1 where
a. The said photo-detector is replaced by a fast photo-detector operating in the GHz range
b. The LF generator and the FLL circuit are replaced by a microwave amplifier whose output is used for injection locking of the microwave generator,
This forms an optoelectronic oscillator oscillating at the hyperfine frequency.

3. The standard of claim 1 where
a. The said photo-detector is replaced by a fast photo-detector operating in the GHz range
b. The said LF generator, the FLL circuit and the microwave generator are replaced by a microwave amplifier whose output is used for injection locking of the microwave generator,
This forms an optoelectronic oscillator oscillating at the hyperfine frequency.

4. The standard of claim 1 where the RF generator comprises of an oscillator and a frequency multiplier and synthesizer that together produce an output at said RF frequency.

5. The standard of claims 1-3 wherein the one laser is replaced by a pair of lasers, the frequencies of said lasers being separated by the hyperfine frequency of said alkali metal atoms and each laser is modulated at a low frequency.

6. The standard of claim 5 wherein said lasers are phase locked.

7. The standard of claim 5 wherein the said separation of frequencies is implemented by frequency locking of said lasers.

8. The standard of claims 1-7 wherein each said laser is a Vertical Cavity Surface Emitting Laser (VCSEL).

9. The standard of claims 1-7 wherein each said laser is a distributed feedback (DFB) laser

10. The standard of claim 1-7 wherein each said laser is a multi section distributed feedback (multi section DFB) laser where the phase control section is used for the PM modulation

11. The standard of claim 1-7 wherein each said laser is a distributed Bragg reflector (DBR) laser

12. The standard of claims 1-3 wherein said atoms are selected from the group consisting of Cesium, Rubidium, Potassium, Sodium or any other element in which CPT phenomenon could be observed.

13. The standard of claim 1-3 wherein an interior surface of said cell comprises an inert coating selected to prevent wall relaxation of alkali metal atoms contacting the said interior surface.

14. The standard of claim 13 wherein said inert coating is a long chain paraffin wax.
